(19) United States
(12) Patent Application Publication
(10) Pub. No.: US 2024/0413185 A1
(43) Pub. Date: Dec. 12, 2024

(54) SEMICONDUCTOR APPARATUS AND METHOD FOR MANUFACTURING SEMICONDUCTOR APPARATUS

(71) Applicant: SONY SEMICONDUCTOR SOLUTIONS CORPORATION, Kanagawa (JP)

(72) Inventor: Tetsuo GOCHO, Kanagawa (JP)

(73) Assignee: SONY SEMICONDUCTOR SOLUTIONS CORPORATION, Kanagawa (JP)

(21) Appl. No.: 18/697,548

(22) PCT Filed: Aug. 19, 2022
(86) PCT No.: PCT/JP2022/031293

§ 371 Date: Apr. 1, 2024

(30) Foreign Application Priority Data
Oct. 8, 2021 (JP) 2021-165853

(51) Int. Cl. H01L 27/146; H01L 21/768; H01L 23/00

(52) U.S. Cl. CPC H01L 27/14636; H01L 21/76898; H01L 24/08; H01L 24/80; H01L 21/76831; H01L 21/76877; H01L 27/14643; H01L 2224/08225; H01L 2224/80895; H01L 2224/80896

(57) ABSTRACT

To reduce an impact due to dry etching performed when a via is formed in a substrate. A first base substrate includes first and second semiconductor substrates. A pixel region is formed on the first semiconductor substrate. A logic circuit that processes a pixel signal output from the pixel region is formed on the second semiconductor substrate. The first base substrate includes a first via that passes through a wiring layer of the logic circuit to a back surface of the first base substrate. A second base substrate includes a connection portion and a second via. The connection portion is connected to the first via of the first base substrate on a front surface of the second base substrate. The connection portion and an electrode situated in a lowest surface of the second base substrate are electrically connected to each other through the second via using a conductive material.

### TECHNICAL FIELD

The present technology relates to a semiconductor apparatus. In particular, the present technology relates to a semiconductor apparatus and a method for manufacturing the semiconductor apparatus, the semiconductor apparatus including stacked semiconductor substrates of a plurality of semiconductor substrates including electrically connected multilayer wiring.

### BACKGROUND ART

A wafer-level chip size package (CSP) (WLCSP) obtained by making a semiconductor apparatus smaller into a chip size in order to make the semiconductor apparatus smaller in size, has been used. The following has been proposed as a structure of a WLCSP of a solid-state imaging apparatus. Glass is bonded to a front-surface-type solid-state imaging apparatus on which a color filter and an on-chip lens are formed, and a cavity structure is formed. Then, a through hole and rewiring are formed on a side of a silicon substrate of the solid-state imaging apparatus to provide a solder ball. This makes it possible to make the area of a chip smaller by taking a pad electrode of a semiconductor apparatus out of a side of a back surface of the chip, compared to a structure in which the pad electrode is arranged in an outer peripheral portion of a circuit to be taken using wire bonding. For example, a method that includes forming, from a side of a back surface of a chip, a via that passes through silicon of a substrate (through-silicon via, TSV), forming a via and wiring that are connected to a pad electrode situated inside of the chip, and forming an electrode on the back surface of the chip has been proposed (for example, refer to Patent Literature 1).

### CITATION LIST

### Patent Literature

Patent Literature 1: Japanese Patent Application Laid-open No. 2015-135938

### DISCLOSURE OF INVENTION

### Technical Problem

However, when a via is formed in a thick substrate such as a silicon substrate layer of a chip, the characteristics of a transistor in the chip that is connected to a pad electrode in the chip may be changed by being affected by charges caused by dry etching performed upon opening a via. Such a phenomenon is called plasma-induced damage (PID), and may result in a change in a threshold for the characteristics of a transistor, an increase in current of leakage through a gate insulation film, a reduction in yield of a semiconductor product or a malfunction in the semiconductor product. It is known that the PID has a greater impact as a via becomes deeper.

The present technology has been made in view of the circumstances described above, and it is a primary object of the present technology to reduce an impact due to dry etching performed when a via is formed in a substrate.

### Solution to Problem

The present technology has been made in order to solve the issues described above, and a first aspect of the present technology is a semiconductor apparatus that includes a first base substrate that is formed by stacking a first semiconductor substrate and a second semiconductor substrate, the first semiconductor substrate being a semiconductor substrate on which a pixel region that performs photoelectric conversion is formed, the second semiconductor substrate being a semiconductor substrate on which a logic circuit is formed, the logic circuit processing a pixel signal that is output from the pixel region, the first base substrate including a first via that passes through a wiring layer of the logic circuit to a back surface of the first base substrate; and a second base substrate that includes a connection portion that is connected to the first via of the first base substrate on a front surface of the second base substrate, and a second via through which the connection portion and an electrode situated in a lowest surface of the second base substrate are electrically connected to each other using a conductive material. As described above, the second via in the second base substrate is formed separately from the via in the first base substrate. This results in providing an effect of reducing an impact on the logic circuit of the first base substrate.

Further, in the first aspect, the second base substrate favorably has a thickness greater than a depth of the first via. This results in providing an effect of further reducing the impact on the logic circuit of the first base substrate.

Furthermore, in the first aspect, the second base substrate may include a plurality of the second vias.

Further, in the first aspect, the second base substrate may include an insulation layer in which the second via is opened. In this case, it is conceivable that the insulation layer in which the second via is opened could be, for example, a silicon dioxide film. On the other hand, in the first aspect, the second base substrate may include a silicon layer in which the second via is opened.

Furthermore, in the first aspect, the connection portion of the second base substrate may be larger in size than a diameter of the first via. This results in providing an effect of ensuring a margin upon connecting the first and second vias.

Further, in the first aspect, the second base substrate may include a wiring layer on a route that electrically connects the connection portion and the electrode. This results in providing an effect of ensuring a degree of freedom in arrangement of the second via in the second base substrate.

Furthermore, in the first aspect, the second base substrate may include, on the lowest surface, a bump that is electrically connected to the electrode.

Further, a second aspect of the present technology is a method for manufacturing a semiconductor apparatus, the method including forming a first base substrate by stacking a first semiconductor substrate and a second semiconductor substrate, the first semiconductor substrate being a semiconductor substrate on which a pixel region that performs photoelectric conversion is formed, the second semiconductor substrate being a semiconductor substrate on which a logic circuit is formed, the logic circuit processing a pixel signal that is output from the pixel region; forming an insulation film on a back surface of the first base substrate; forming a first opening in a conductive material situated inside of the first base substrate; forming an insulation film sidewall in the first opening; filling a conductive material into a space of the first opening that is situated further inward than the insulation film sidewall; smoothing the conductive material; forming a second opening in a second base substrate that is different from the first base substrate; forming an insulation film on a back surface of the second base substrate; filling a conductive material into the second opening; smoothing the conductive material; bonding the first base substrate and the second base substrate such that the conductive material in the first opening of the first base substrate and the conductive material in the second opening of the second base substrate are connected to each other; and removing a substrate of the second base substrate until a portion of a conductive material situated inside of the second base substrate is exposed. As described above, the second via in the second base substrate is formed separately from the via in the first base substrate. This results in providing an effect of reducing an impact on the logic circuit of the first base substrate.

Further, in the second aspect, the forming the first opening may include forming the first opening in at least a silicon layer.

Furthermore, in the second aspect, making a material of an upper portion of the first base substrate thinner may be further included after the bonding the first base substrate and the second base substrate. In this case, it is conceivable that the material of the upper portion of the first base substrate could be, for example, silicon.

### BRIEF DESCRIPTION OF DRAWINGS

FIG. 1 illustrates an example of an overall configuration of a solid-state imaging apparatus according to embodiments of the present technology that is an example of a semiconductor apparatus including an imaging device.

FIG. 2 illustrates an example of dividing the solid-state imaging apparatus according to the embodiments of the present technology into substrates.

FIG. 3 illustrates an example of a structure of a cross section of the solid-state imaging apparatus according to a first embodiment of the present technology.

FIG. 4 illustrates a first example of the solid-state imaging apparatus according to the first embodiment of the present technology.

FIG. 5 illustrates examples of a shape of a via 235 of the solid-state imaging apparatus according to the first embodiment of the present technology.

FIG. 6 illustrates a second example of the solid-state imaging apparatus according to the first embodiment of the present technology.

FIG. 7 illustrates a third example of the solid-state imaging apparatus according to the first embodiment of the present technology.

FIG. 8 illustrates a fourth example of the solid-state imaging apparatus according to the first embodiment of the present technology.

FIG. 9 illustrates a fifth example of the solid-state imaging apparatus according to the first embodiment of the present technology.

FIG. 10 illustrates the fifth example of the solid-state imaging apparatus according to the first embodiment of the present technology.

FIG. 11 illustrates the fifth example of the solid-state imaging apparatus according to the first embodiment of the present technology.

FIG. 12 illustrates the fifth example of the solid-state imaging apparatus according to the first embodiment of the present technology.

FIG. 13 illustrates an example of a procedure of a method for manufacturing a first base substrate 100 according to the first embodiment of the present technology.

FIG. 14 illustrates the example of the procedure of the method for manufacturing the first base substrate 100 according to the first embodiment of the present technology.

FIG. 15 illustrates an example of a procedure of a method for manufacturing the second base substrate 200 according to the first embodiment of the present technology.

FIG. 16 illustrates the example of the procedure of the method for manufacturing the second base substrate 200 according to the first embodiment of the present technology.

FIG. 17 illustrates the example of the procedure of the method for manufacturing the second base substrate 200 according to the first embodiment of the present technology.

FIG. 18 illustrates a first modification of the second base substrate 200 according to the first embodiment of the present technology.

FIG. 19 illustrates a second modification of the second base substrate 200 according to the first embodiment of the present technology.

FIG. 20 illustrates an example of a procedure of a method for manufacturing the solid-state imaging apparatus according to the first embodiment of the present technology.

FIG. 21 illustrates the example of the procedure of the method for manufacturing the solid-state imaging apparatus according to the first embodiment of the present technology.

FIG. 22 illustrates the example of the procedure of the method for manufacturing the solid-state imaging apparatus according to the first embodiment of the present technology.

FIG. 23 illustrates the example of the procedure of the method for manufacturing the solid-state imaging apparatus according to the first embodiment of the present technology.

FIG. 24 illustrates an example of a structure of a cross section of the solid-state imaging apparatus according to a second embodiment of the present technology.

FIG. 25 illustrates an example of a procedure of a method for manufacturing the second base substrate 200 according to the second embodiment of the present technology.

FIG. 26 illustrates the example of the procedure of the method for manufacturing the second base substrate 200 according to the second embodiment of the present technology.

FIG. 27 illustrates an example of a structure of a cross section of the solid-state imaging apparatus according to a third embodiment of the present technology.

FIG. 28 illustrates an example of a procedure of a method for manufacturing the second base substrate 200 according to the third embodiment of the present technology.

FIG. 29 illustrates the example of the procedure of the method for manufacturing the second base substrate 200 according to the third embodiment of the present technology.

### MODE(S) FOR CARRYING OUT THE INVENTION

Embodiments for carrying out the present technology (hereinafter referred to as “embodiments”) will now be described below. The description is made in the following order.
1. First Embodiment (Technology Used to Form Deep Via Separately and Perform Bonding)
2. Second Embodiment (Example of High Aspect Ratio of Opening of Via)
3. Third Embodiment (Example of Forming Via in Silicon Substrate)

### 1. First Embodiment

### [Overall Configuration of Solid-State Imaging Apparatus]

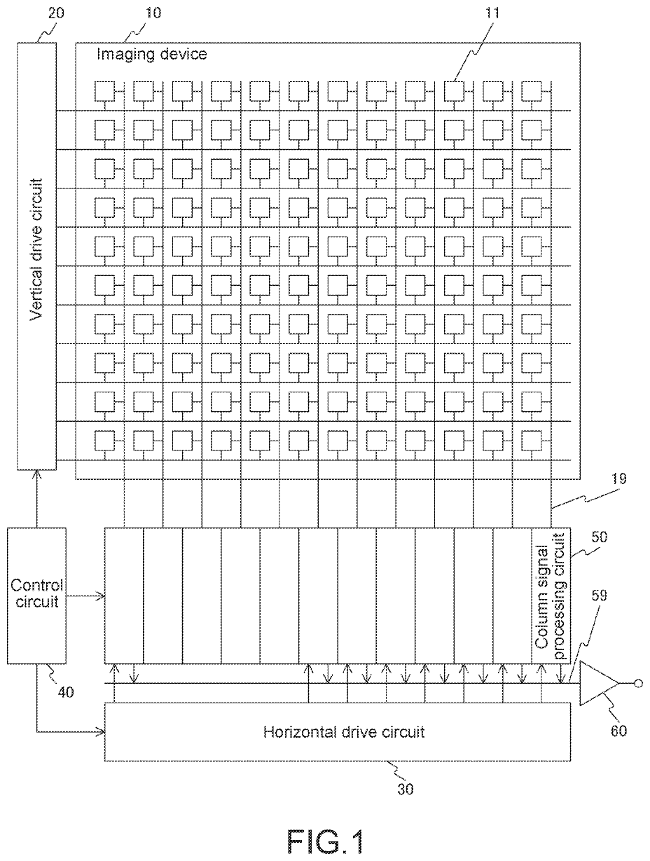

FIG. 1 illustrates an example of an overall configuration of a solid-state imaging apparatus according to the embodiments of the present technology that is an example of a semiconductor apparatus including an imaging device. The solid-state imaging apparatus is a complementary metal-oxide semiconductor (CMOS) image sensor. The solid-state imaging apparatus includes an imaging device 10 and a peripheral circuit section on a semiconductor substrate (such as a silicon substrate) (not illustrated). The peripheral circuit section includes a vertical drive circuit 20, a horizontal drive circuit 30, a control circuit 40, a column signal processing circuit 50, and an output circuit 60.

The imaging device 10 is a pixel array in which a plurality of pixels 11 each including a photoelectric converter is arranged in a two-dimensional array. The pixel 11 includes, for example, a photodiode that corresponds to the photoelectric converter, and a plurality of pixel transistors. Here, the plurality of pixel transistors may include, for example, three transistors that are a transfer transistor, a reset transistor, and an amplification transistor. Further, the plurality of pixel transistors may also include four transistors by a selection transistor being added to the three transistors. Note that an equivalent circuit of a unit pixel is similar to a typical one. Thus, a detailed description thereof is omitted.

Further, the pixel 11 may be a unit pixel, or a shared pixel structure may be provided for the pixels 11. The pixel sharing structure refers to a structure in which a plurality of photodiodes shares a floating diffusion and a transistor other than a transfer transistor.

The vertical drive circuit 20 drives the pixel 11 for each row. The vertical drive circuit 20 includes, for example, a shift register. The vertical drive circuit 20 selects pixel drive wiring and supplies a pulse used to drive the pixel 11 to the selected pixel drive wiring. Consequently, the vertical drive circuit 20 vertically selectively scans the pixels 11 of the imaging device 10 successively for each row, and supplies the column signal processing circuit 50 with a pixel signal based on signal charges generated by the photoelectric converter of each pixel 11 according to an amount of light received.

The horizontal drive circuit 30 drives the column signal processing circuits 50 for each column. The horizontal drive circuit 30 includes, for example, a shift register. The horizontal drive circuit 30 successively outputs a horizontally scanning pulse to select the column signal processing circuits 50 in sequence, and causes a pixel signal to be output from each column signal processing circuit 50 to a horizontal signal line 59.

The control circuit 40 controls the entirety of the solid-state imaging apparatus. The control circuit 40 receives an input clock, and data used to give an instruction on, for example, an operation mode, and outputs data such as inside information regarding the inside of the solid-state imaging apparatus. In other words, the control circuit 40 generates a clock signal and a control signal on the basis of a vertical synchronization signal, a horizontal synchronization signal, and a master clock, where, for example, the vertical drive circuit 20, the column signal processing circuit 50, and the horizontal drive circuit 30 operate on the basis of the clock signal and the control signal. Then, the control circuit 40 inputs the generated signals to, for example, the vertical drive circuit 20, the column signal processing circuit 50, and the horizontal drive circuit 30.

For example, the column signal processing circuits 50 are arranged for each column of the pixels 11, and perform signal processing such as denoising for each pixel column with respect to a signal output from the pixels 11 included in a row. In other words, the column signal processing circuit 50 performs signal processing such as correlated double sampling (CDS) used to remove fixed-pattern noise specific to the pixel 11, signal amplification, and analog/digital (AD) conversion. A horizontal selection switch (not illustrated) is connected on the output side of the column signal processing circuit 50 between the column signal processing circuit 50 and the horizontal signal line 59.

The output circuit 60 performs signal processing on signals successively supplied by the respective column signal processing circuits 50 through the horizontal signal line 59, and outputs the signals. Here, the output circuit 60 buffers the signal coming from the column signal processing circuit 50. Further, the output circuit 60 may perform, for example, black level adjustment, correction for variation in column, and various digital signal processing with respect to the signal coming from the column signal processing circuit 50.

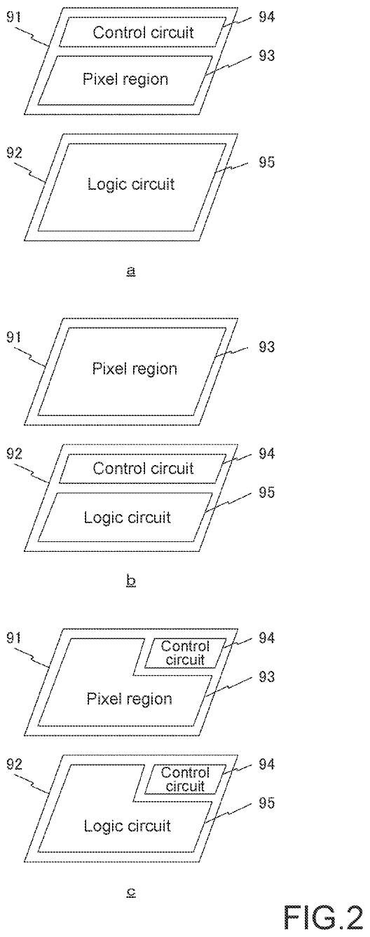

FIG. 2 illustrates an example of dividing the solid-state imaging apparatus according to the embodiments of the present technology into substrates.

(a) of the figure illustrates a first example. The first example includes a first semiconductor substrate 91 and a second semiconductor substrate 92. The first semiconductor substrate 91 includes a pixel region 93 and a control circuit 94. The second semiconductor substrate 92 includes a logic circuit 95 including a signal processing circuit. Further, the first semiconductor substrate 91 and the second semiconductor substrate 92 are electrically connected to each other to provide a solid-state imaging apparatus in the form of a semiconductor chip.

(b) of the figure illustrates a second example. The second example includes the first semiconductor substrate 91 and the second semiconductor substrate 92. The first semiconductor substrate 91 includes the pixel region 93. The second semiconductor substrate 92 includes the control circuit 94 and the logic circuit 95 including the signal processing circuit. Further, the first semiconductor substrate 91 and the second semiconductor substrate 92 are electrically connected to each other to provide a solid-state imaging apparatus in the form of a semiconductor chip.

(c) of the figure illustrates a third example. The third example includes the first semiconductor substrate 91 and the second semiconductor substrate 92. The first semiconductor substrate 91 includes the pixel region 93 and the control circuit 94 controlling the pixel region 93. The second semiconductor substrate 92 includes the logic circuit 95 including the signal processing circuit, and the control circuit 94 controlling the logic circuit 95. Further, the first semiconductor substrate 91 and the second semiconductor substrate 92 are electrically connected to each other to provide a solid-state imaging apparatus in the form of a semiconductor chip.

### [Structure of Cross Section of Solid-State Imaging Apparatus]

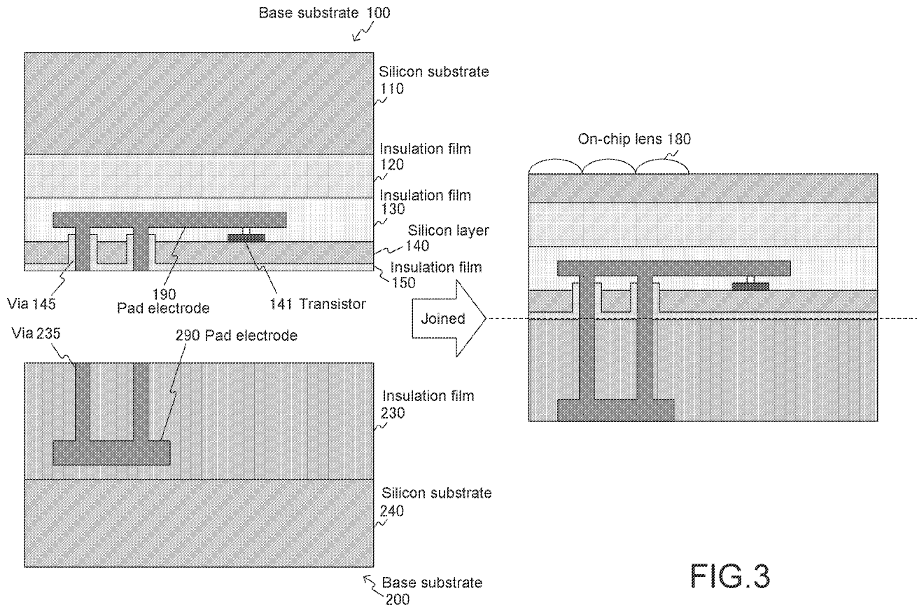

FIG. 3 illustrates an example of a structure of a cross section of the solid-state imaging apparatus according to a first embodiment of the present technology.

In the first embodiment, a first base substrate 100 and a second base substrate 200 are manufactured separately from each other, and then the first base substrate 100 and the second base substrate 200 are bonded to each other to avoid forming a deep TSV, in order to reduce an impact on the characteristics of a transistor. In other words, a shallow via 145 is formed in the first base substrate 100 in which a transistor 141 that is an internal circuit is formed, and a deep via 235 is formed in the second base substrate 200 different from the first base substrate 100. In other words, the second base substrate 200 has a thickness greater than a depth of the shallow via 145 in the first base substrate 100. Then, the first base substrate 100 and the second base substrate 200 are bonded to each other such that the shallow via 145 and the deep via 235 are electrically connected to each other.

The first base substrate 100 is formed by stacking a silicon substrate 110, insulation films 120 and 130, a silicon layer 140, and an insulation film 150 that are arranged in this order from a front surface of the first base substrate 100. Further, a pad electrode 190 is formed above the silicon layer 140. Note that the pad electrode 190 includes a pad electrode and wiring in a broad concept. The second base substrate 200 is formed by stacking an insulation film 230 and a silicon substrate 240 that are arranged in this order from a front surface of the second base substrate 200. The shallow via 145 in the first base substrate 100 passes through the silicon layer 140. The deep via 235 in the second base substrate 200 is formed in the insulation film 230.

Here, the first semiconductor substrate 91 described above corresponds to a portion that includes the silicon substrate 110 and the insulation film 120. Further, the second semiconductor substrate 92 corresponds to a portion that includes the insulation film 130 and portions under the insulation film 130. In other words, a boundary of the first semiconductor substrate 91 including the pixel region 93 and the second semiconductor substrate 92 including the logic circuit 95 is situated between the insulation film 120 and the insulation film 130.

After the first base substrate 100 and the second base substrate 200 are bonded to each other, the silicon substrate 240 and a lower portion of the insulation film 230 are removed to expose the pad electrode 290 on a back surface of the second base substrate 200. Further, after an upper side of the silicon substrate 110 is smoothed, an on-chip lens 180 is formed thereon.

Note that the insulation films 120, 130, 150, and 230 are primarily formed of a silicon dioxide film such as SiO2. Specifically, a SiN film or the like is used as the insulation film 120 insulating a wiring layer in the pixel region 93. Further, a stacking structure obtained by stacking certain types of films such as an SiOC film and an SiCN film is adopted in the insulation film 130 in the logic circuit 95, in order to obtain a low dielectric constant.

### First Example

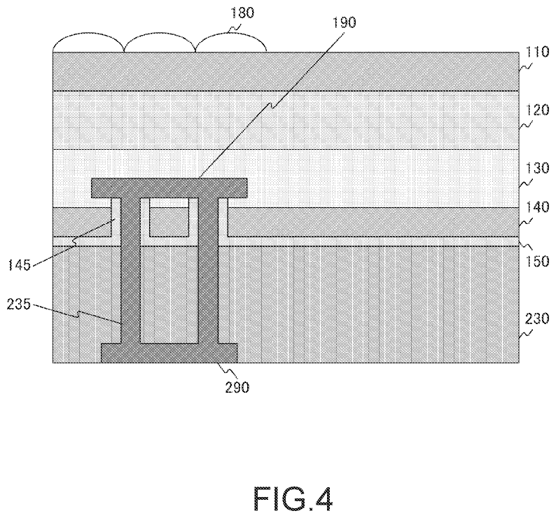

FIG. 4 illustrates a first example of the solid-state imaging apparatus according to the first embodiment of the present technology.

The first example has a basic configuration that is similarly provided by the embodiments described above. In other words, a conductive material in the via 145 formed in the silicon layer 140 and a conductive material in the via 235 formed in the insulation film 230 are linearly electrically connected to each other. This makes it possible to conduct a signal of the pad electrode 190 in the first base substrate 100 to the pad electrode 290 situated on the back surface of the second base substrate 200.

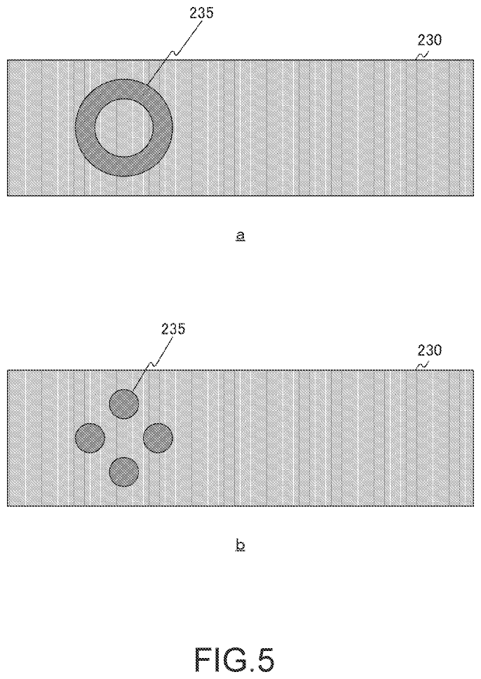

FIG. 5 illustrates examples of a shape of the via 235 of the solid-state imaging apparatus according to the first embodiment of the present technology. The figure illustrates two examples of the insulation film 230 planarly cut.

As illustrated in (a) of the figure, the via 235 may have a doughnut-shaped cross section. In this case, it is conceivable that the via 235 could be filled with a conductive material (such as copper).

Further, as illustrated in (b) of the figure, a plurality of vias 235 each having a shape of a slim cylinder may be formed. In this case, it is conceivable that the cylinder of the via 235 could be filled with a conductive material (such as copper).

### Second Example

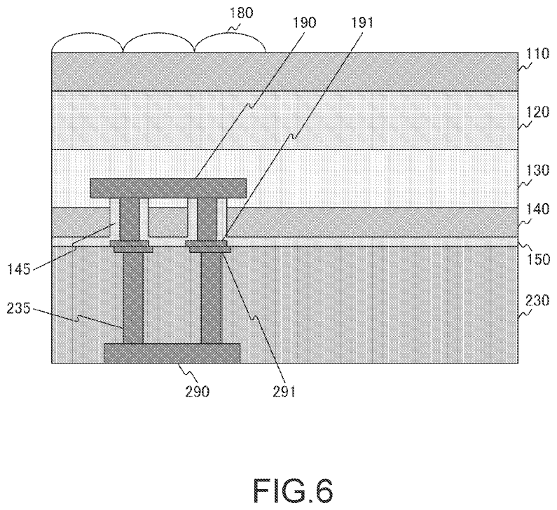

FIG. 6 illustrates a second example of the solid-state imaging apparatus according to the first embodiment of the present technology.

In the second example, a separate pad electrode 191 is provided on a back surface of the first base substrate 100 for each via 145, and a separate pad electrode 291 is provided on an upper surface of the second base substrate 200 for each via 235. This makes it possible to ensure a margin for misalignment of the first base substrate 100 and the second base substrate 200 that is caused when the first base substrate 100 and the second base substrate 200 are bonded to each other. Here, when the pad electrodes 191 and 291 are made of a copper material, this enables Cu—Cu junction.

### Third Example

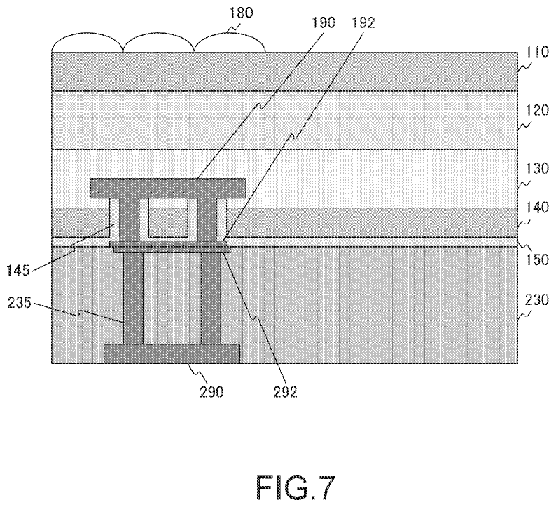

FIG. 7 illustrates a third example of the solid-state imaging apparatus according to the first embodiment of the present technology.

The third example is similar to the second example described above. One pad electrode 192 is provided for a plurality of vias 145 on the back surface of the first base substrate 100, and one pad electrode 292 is provided for a plurality of vias 235 on the upper surface of the second base substrate 200. This makes it possible to further ensure a margin for misalignment of the first base substrate 100 and the second base substrate 200 that is caused when the first base substrate 100 and the second base substrate 200 are bonded to each other.

### Fourth Example

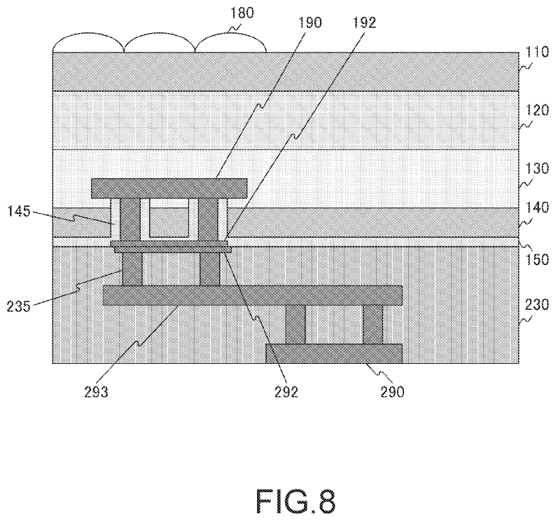

FIG. 8 illustrates a fourth example of the solid-state imaging apparatus according to the first embodiment of the present technology.

In the fourth example, a multistage route is further formed in the configuration of the third example described above using a wiring layer 293. This makes it possible to change a position of the pad electrode 290 on the back surface of the second base substrate 200. In other words, an upper surface of and a lower surface of the via 235 in the second base substrate 200 are aligned in the third example, whereas the upper and lower surfaces do not necessarily have to be aligned in the fourth example. This makes it possible to improve a degree of freedom in the position of the pad electrode 290.

### Fifth Example

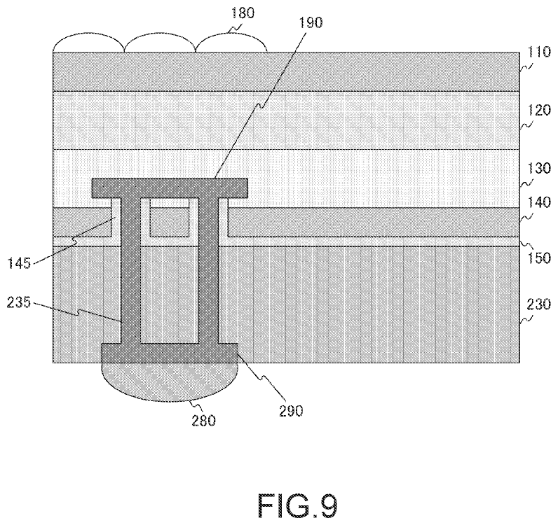

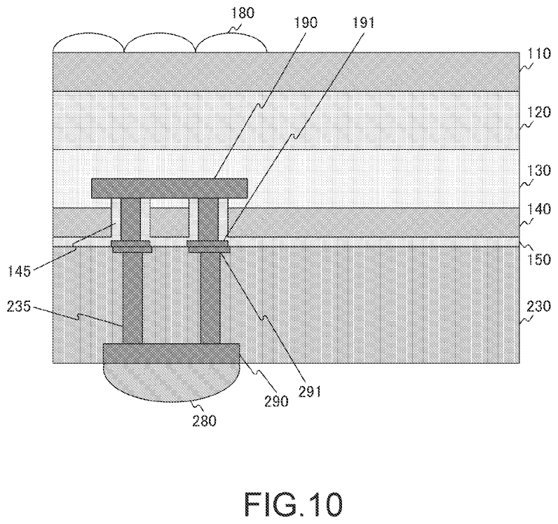

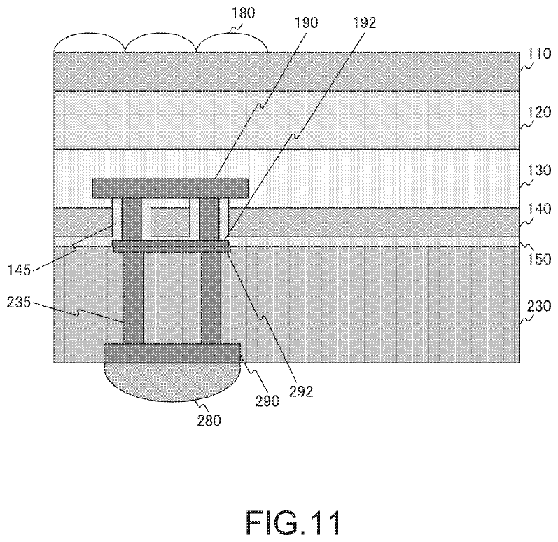

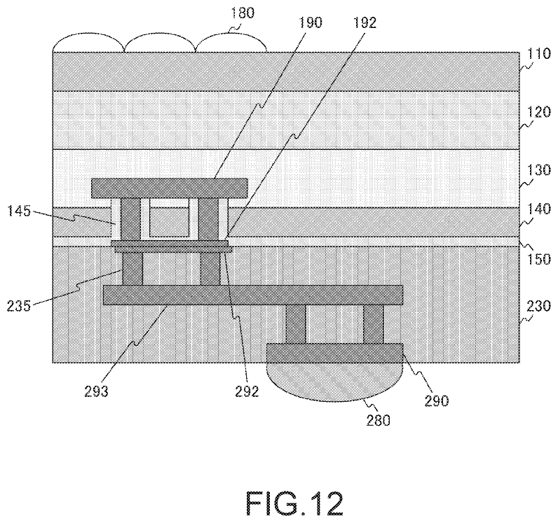

FIGS. 9 to 12 each illustrate a fifth example of the solid-state imaging apparatus according to the first embodiment of the present technology.

In the fifth example, a bump 280 is provided to the pad electrode 290 on the back surface of the second base substrate 200 in each of the configurations of the first to fourth examples described above. Flat connection is made in each of the first to fourth examples, whereas connection using the bump 280 is made in the fifth example.

### [Method for Manufacturing Solid-State Imaging Apparatus]

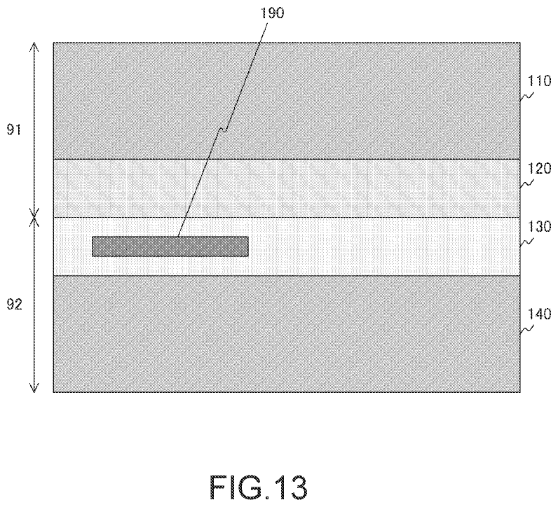

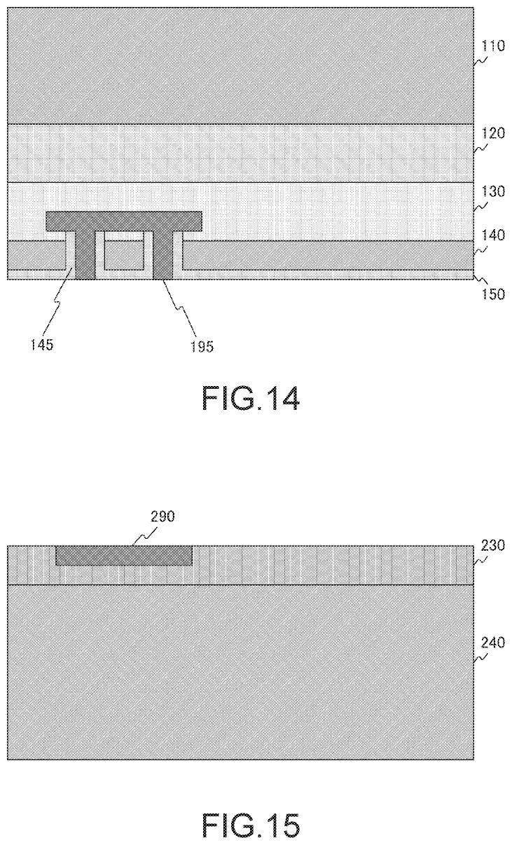

FIGS. 13 and 14 illustrate an example of a procedure of a method for manufacturing the first base substrate 100 according to the first embodiment of the present technology.

First, as illustrated in FIG. 13, a wafer of the first semiconductor substrate 91 including the silicon substrate 110 and the insulation film 120 and a wafer of the second semiconductor substrate 92 including the insulation film 130 and the silicon layer 140 are joined to each other. The pad electrode 190 is formed in the insulation film 130. Note that the figure does not illustrate a device or wiring in the wafer of the first semiconductor substrate 91, or a device in the wafer of the second semiconductor substrate 92.

Next, as illustrated in FIG. 14, the silicon layer 140 is polished by chemical mechanical polishing (CMP) until the silicon layer 140 has a thickness of about several micrometers (for example, 3 to 10 μm). Thereafter, the insulation film 150 is formed on a back surface of the silicon layer 140 using chemical vapor deposition (CVD).

Then, the via 145 is formed in the silicon layer 140 under the pad electrode 190 using photoresist and by dry etching. An insulation film sidewall is formed on a side surface of the via 145 using CVD and etching-back. Then, the via 145 is filled with a conductive material 195 (such as copper) using plating, and polishing is performed by CMP. Accordingly, the first base substrate 100 is formed.

FIGS. 15 to 17 illustrate an example of a procedure of a method for manufacturing the second base substrate 200 according to the first embodiment of the present technology.

First, as illustrated in FIG. 15, the insulation film 230 is formed on the silicon substrate 240 using CVD. Then, a groove is formed in a portion of the insulation film 230 and the portion is plated with a conductive material (such as copper) in order to form the pad electrode 290, and polishing is performed by CMP.

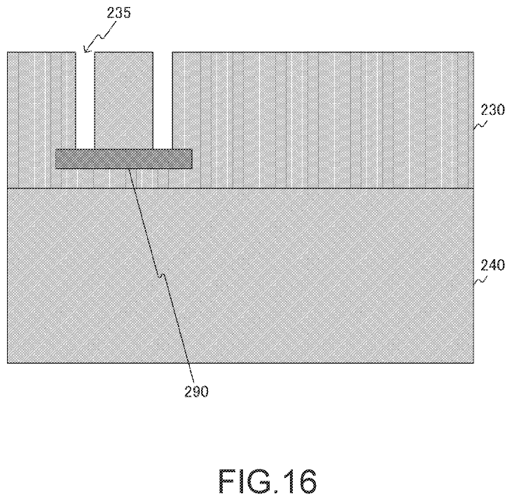

Then, as illustrated in FIG. 16, the insulation film 230 is grown up to, for example, about 150 micrometers using, for example, CVD or bonding of glass. Then, the via 235 is opened above the pad electrode 290 using photoresist, and etching is performed.

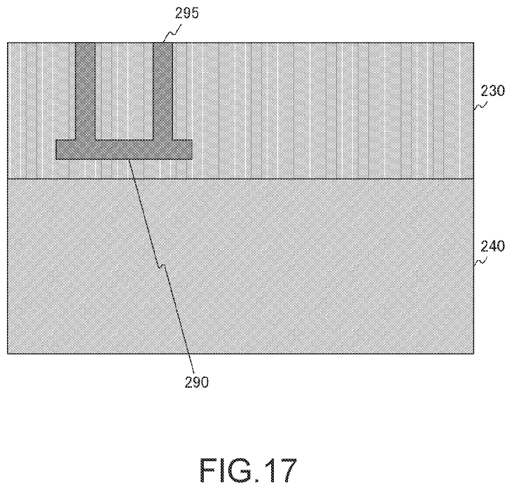

Then, as illustrated in FIG. 17, the via 235 is filled with a conductive material 295 (such as copper) using plating, and polishing is performed by CMP. Accordingly, the second base substrate 200 is formed.

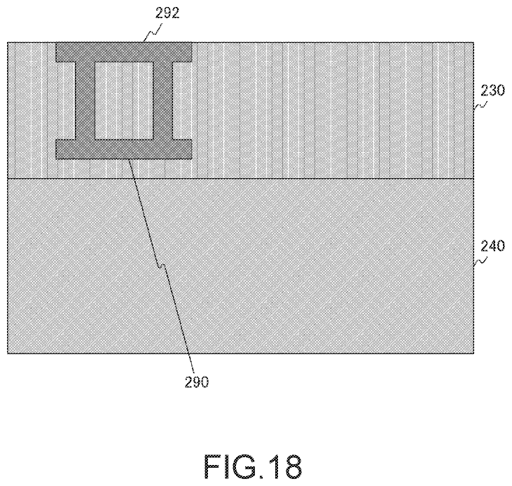

FIG. 18 illustrates a first modification of the second base substrate 200 according to the first embodiment of the present technology.

As described in Example 3 described above, the pad electrode 292 may be formed on the via 235. In this case, the repetition of the procedure described above makes it possible to further grow the insulation film 230, and to form the pad electrode 292 using plating and CMP.

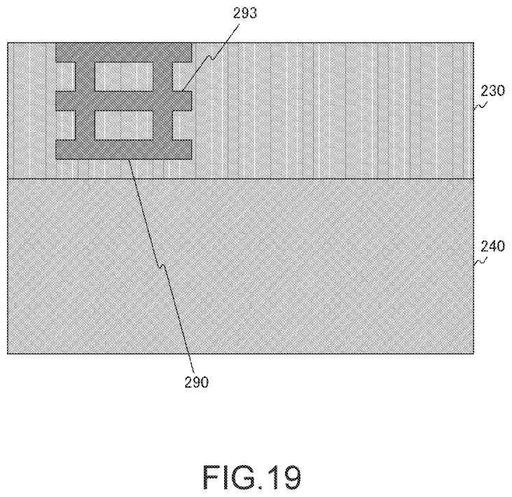

FIG. 19 illustrates a second modification of the second base substrate 200 according to the first embodiment of the present technology.

As described in Example 4 described above, the wiring layer 293 may be formed in the middle of the route of the via 235. In this case, the repetition of the procedure described above makes it possible to grow the insulation film 230 in multiple stages, and to form the wiring layer 293 using plating and CMP.

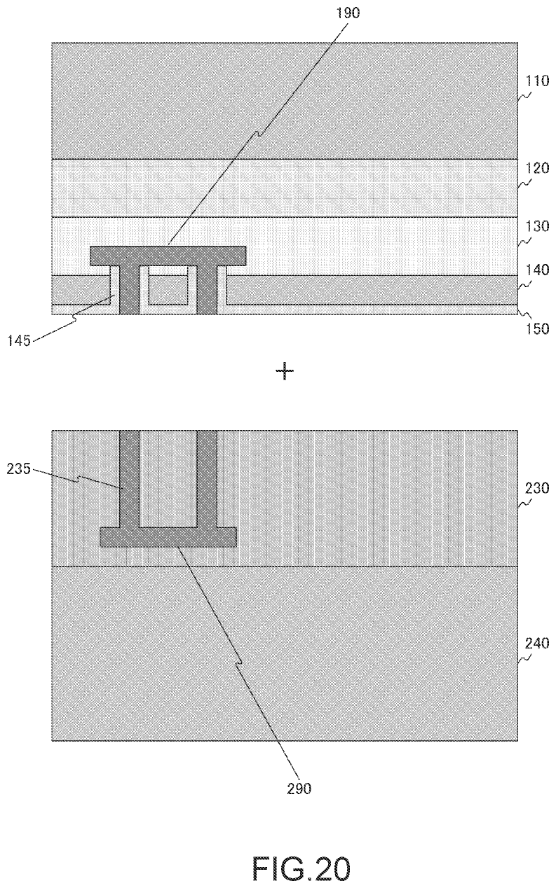

FIGS. 20 to 23 illustrate an example of a procedure of a method for manufacturing the solid-state imaging apparatus according to the first embodiment of the present technology.

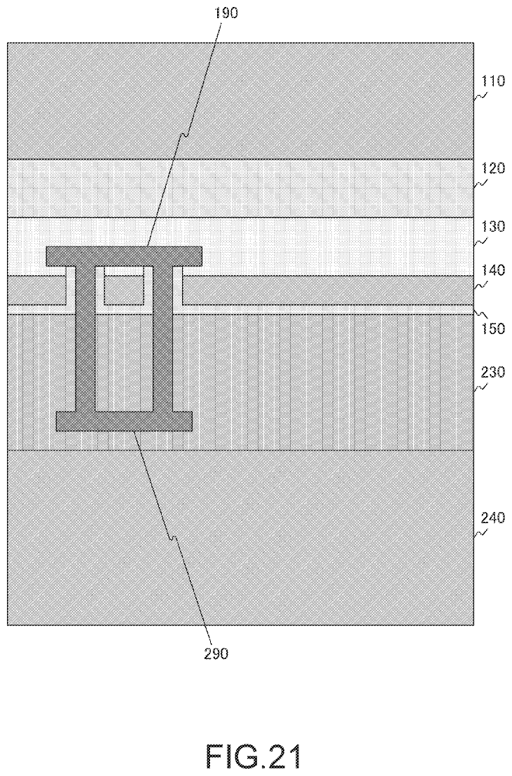

As illustrated in FIG. 20, the first base substrate 100 and second base substrate 200 formed by the respective procedures described above are bonded to each other such that the conductive material of the via 145 and the conductive material of the via 235 are electrically connected to each other. Consequently, electrical connection is made between the pad electrode 190 and the pad electrode 290, as illustrated in FIG. 21.

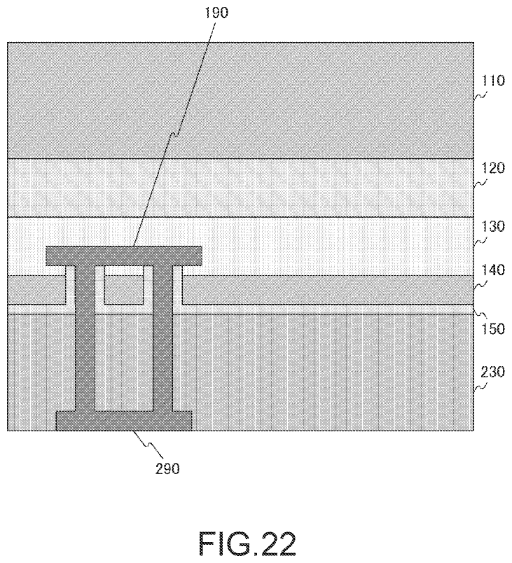

Thereafter, a lower portion that is the silicon substrate 240 is removed using CMP or silicon etching, as illustrated in FIG. 22. Then, the insulation film 230 is removed using CMP until the pad electrode 290 is exposed.

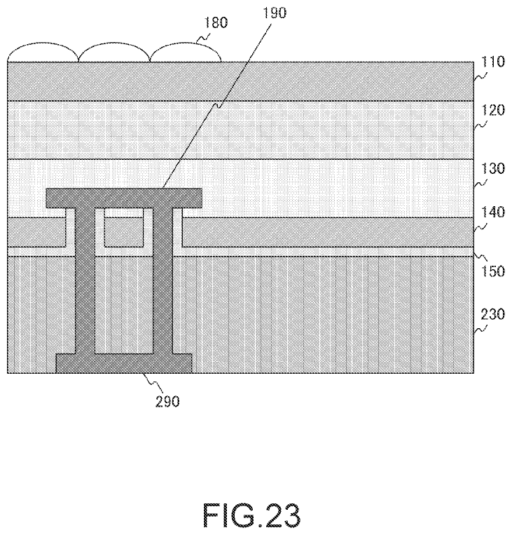

Then, an upper portion of the silicon substrate 110 is polished using CMP until the silicon substrate 110 has a thickness of, for example, about two micrometers, as illustrated in FIG. 23. Thereafter, the on-chip lens 180 is formed on the upper portion of the silicon substrate 110. Accordingly, the solid-state imaging apparatus including the first base substrate 100 and the second base substrate 200 is formed.

As described above, in the first embodiment of the present technology, the deep via 235 is formed in the second base substrate 200, and then the second base substrate 200 is bonded to the first base substrate 100. This makes it possible to avoid an impact on a transistor connected to the shallow via 145 formed in the first base substrate 100.

### 2. Second Embodiment

In the first embodiment described above, it is assumed that the entirety of the via 235 is filled with a conductive material. However, there may be difficulty in performing opening etching when, for example, an opening aspect ratio is high. A method for forming a conductive material in a via without using opening etching is described in this second embodiment. Note that an overall configuration of the solid-state imaging apparatus is similar to that of the first embodiment described above. Thus, a detailed description thereof is omitted.

### [Structure of Cross Section of Solid-State Imaging Apparatus]

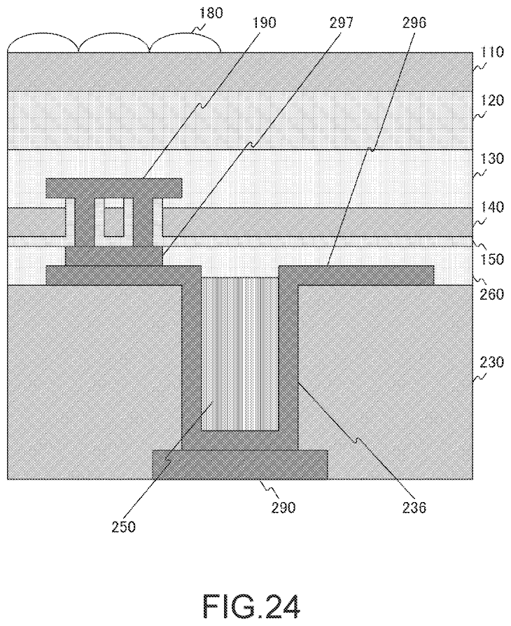

FIG. 24 illustrates an example of a structure of a cross section of the solid-state imaging apparatus according to the second embodiment of the present technology.

In the second embodiment, the solid-state imaging apparatus has a structure in which a conductive material 296 is formed on an inner wall of and above a via 236 in the insulation film 230 and then a resin 250 is filled into a space of the via 236 that is situated further inward than the conductive material 296. Further, a conductive material 297 is further formed on the conductive material 296 in order for the second base substrate 200 to be connected to the first base substrate 100. This results in the pad electrode 190 and the pad electrode 290 being electrically connected to each other.

### [Method for Manufacturing Solid-State Imaging Apparatus]

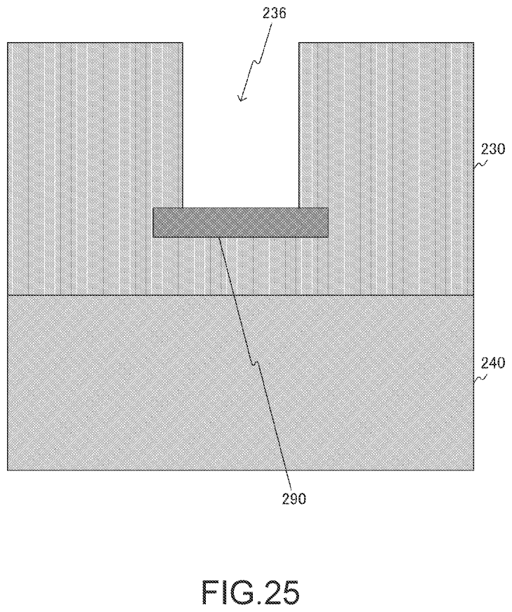

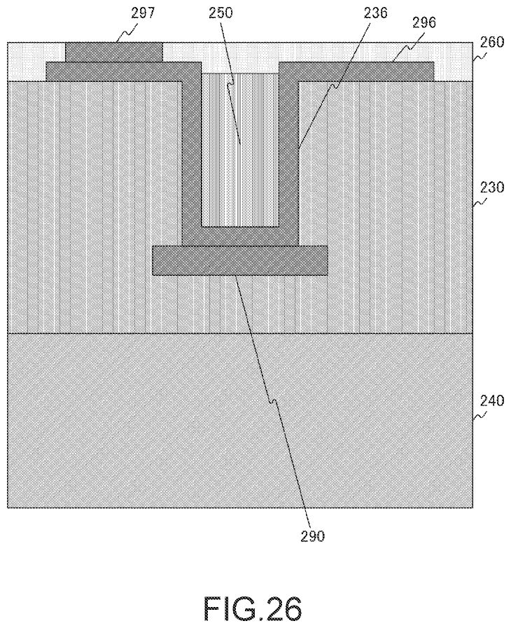

FIGS. 25 and 26 illustrate an example of a procedure of a method for manufacturing the second base substrate 200 according to the second embodiment of the present technology. Note that a method for manufacturing the first base substrate 100 is similar to the method provided by the first embodiment described above. Thus, a detailed description thereof is omitted.

First, as illustrated in FIG. 25, the insulation film 230 is formed on the silicon substrate 240 using CVD. Then, a groove is formed in a portion of the insulation film 230 and the portion is plated with a conductive material (such as copper) in order to form the pad electrode 290, and polishing is performed by CMP.

Thereafter, the insulation film 230 is grown using, for example, CVD or bonding of glass. Then, the via 236 is opened above the pad electrode 290 using photoresist.

Then, as illustrated in FIG. 26, the via 236 is plated with the conductive material 296 (such as copper), and photoresist patterning is performed to form a pattern of the conductive material 296 on the inner wall of and above the via 236.

Then, the resin 250 is applied to a space of the via 236 that is situated further inward than the conductive material 296, and polishing is performed by CMP.

Thereafter, an insulation film 260 is formed on the insulation film 230 using CVD, and polishing is performed by CMP.

Then, photoresist patterning is performed on the insulation film 260, and an opening is formed. The opening is plated with the conductive material 297 (such as copper), and polishing is performed by CMP.

Thereafter, the first base substrate 100 and the second base substrate 200 are joined to each other, and the silicon substrate 240 situated on the back surface of the second base substrate 200 is removed. Further, the insulation film 230 is removed until the pad electrode 290 is exposed.

Furthermore, the upper portion of the silicon substrate 110 is polished by CMP to make the silicon substrate 110 thinner such that the silicon substrate 110 has a thickness of, for example, about two micrometers. Thereafter, the on-chip lens 180 is formed on the upper portion of the silicon substrate 110. Accordingly, the solid-state imaging apparatus according to the second embodiment illustrated in FIG. 24 is formed.

As described above, the second embodiment of the present technology makes it possible to electrically connect the pad electrode 190 and the pad electrode 290 to bond the first base substrate 100 and the second base substrate 200 even when an aspect ratio of an opening of the via 236 of the insulation film 230 is high.

### 3. Third Embodiment

In the second embodiment described above, the via 236 is formed in the insulation film 230. A method for forming a via in the silicon substrate 240 is described in this third embodiment. Note that an overall configuration of the solid-state imaging apparatus is similar to that of the first embodiment described above. Thus, a detailed description thereof is omitted.

### [Structure of Cross Section of Solid-State Imaging Apparatus]

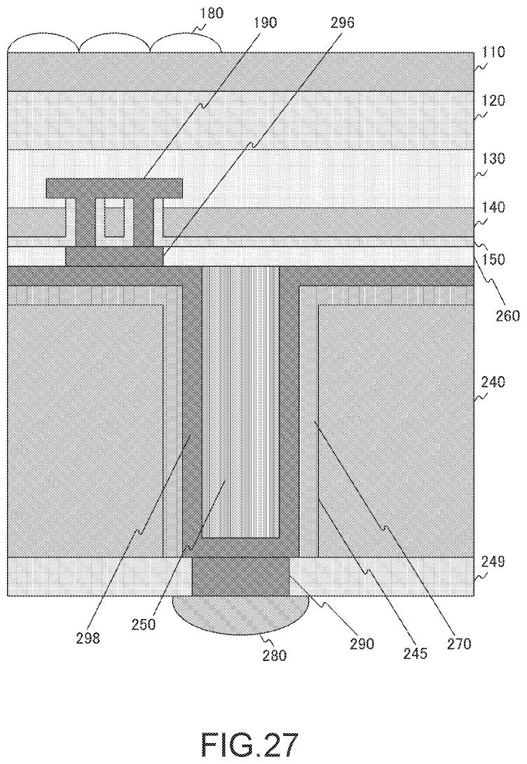

FIG. 27 illustrates an example of a structure of a cross section of the solid-state imaging apparatus according to the third embodiment of the present technology.

In the third embodiment, the solid-state imaging apparatus has a structure in which an insulation film 270 is formed on an inner wall of and on a surface of a via 245 in the silicon substrate 240, then a conductive material 298 is formed over the inner wall of and above the via 245, and the resin 250 is filled into a space of the via 245 that is situated further inward than the conductive material 298. Further, as in the second embodiment, the conductive material 297 is formed on the conductive material 296 in order for the second base substrate 200 to be connected to the first base substrate 100. This results in the pad electrode 190 and the pad electrode 290 being electrically connected to each other.

### [Method for Manufacturing Solid-State Imaging Apparatus]

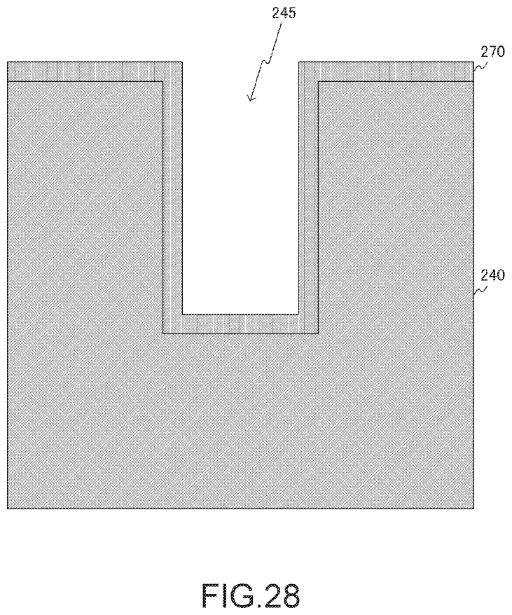

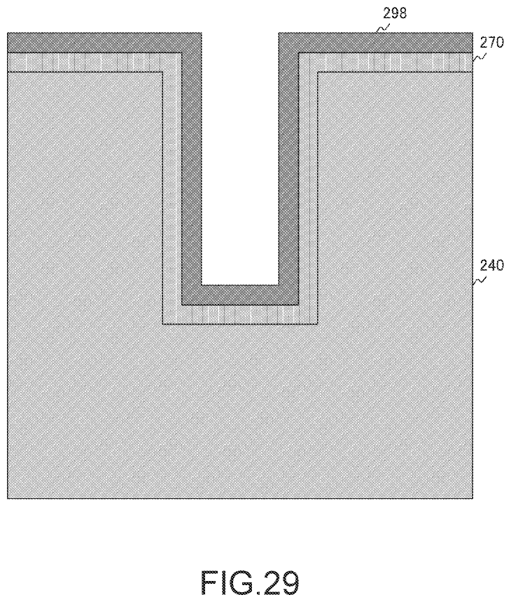

FIGS. 28 and 29 illustrate an example of a procedure of a method for manufacturing the second base substrate 200 according to the third embodiment of the present technology. Note that a method for manufacturing the first base substrate 100 is similar to the method provided by the first embodiment described above. Thus, a detailed description thereof is omitted.

First, as illustrated in FIG. 28, the via 245 is opened in the silicon substrate 240 using opening etching. Further, the insulation film 270 is formed on the silicon substrate 240 using CVD.

Furthermore, as illustrated in FIG. 29, the via 245 is plated with the conductive material 298 (such as copper) on the insulation film 270. Then, the resin 250 is applied to a space of the via 245 that is situated further inward than the conductive material 298, and polishing is performed by CMP.

Thereafter, the insulation film 260 is formed on the conductive material 298 using CVD. Then, photoresist patterning is performed on the insulation film 260, and an opening is formed. The opening is plated with the conductive material 296 (such as copper), and polishing is performed by CMP.

Thereafter, the first base substrate 100 and the second base substrate 200 are joined to each other, and the silicon substrate 240 situated on the back surface of the second base substrate 200 is removed. Further, the insulation film 270 is removed until the conductive material 298 is exposed.

Then, an insulation film 249 is formed on the back surface of the second base substrate 200 using CVD. Then, photoresist patterning is performed on the insulation film 249, and an opening is formed. The opening is plated with a conductive material (such as copper), and polishing is performed by CMP. Accordingly, the pad electrode 290 is formed.

Further, the upper portion of the silicon substrate 110 is polished using CMP to make the silicon substrate 110 thinner such that the silicon substrate 110 has a thickness of, for example, about two micrometers. Thereafter, the on-chip lens 180 is formed on the upper portion of the silicon substrate 110. Accordingly, the solid-state imaging apparatus according to the third embodiment illustrated in FIG. 27 is formed.

Note that, thereafter, the bump 280 (such as copper) may be formed on the back surface of the second base substrate 200, as illustrated in the figure.

As described above, the third embodiment of the present technology also makes it possible to form the conductive material 298 on the inner wall of and above the via 245 in the silicon substrate 240 by use of the insulation film 270 and to bond the first base substrate 100 and the second base substrate 200.

### [Effects]

As described above, in the embodiments of the present technology, the deep via 235 is formed in the second base substrate 200. This makes it possible to reduce an impact that PID has on a transistor of the first base substrate 100. For example, the embodiments make it possible to reduce an amount of a change in a threshold for a transistor up to about 10 millivolt from about several hundred millivolt, which is the conventional amount of a change in the threshold.

Further, conventionally, a transistor is typically arranged at a distance from a TSV in order not to be affected by stress from the TSV. The distance is called a keep-out zone (KOZ). When a conductive material in a via is assumed to be copper, a ratio of a coefficient of thermal expansion of the conductive material to SiO2 is smaller than a ratio of a coefficient of thermal expansion of the conductive material to silicon. Thus, stress from a via can be more reduced when SiO2 is adopted as a base material used to form the via than when silicon is adopted as the base material, where the KOZ can be reduced by about 70%. Consequently, in terms of KOZ, the formation of the deep via 235 in the insulation film 230 as in the first and second embodiments is more advantageous than the formation of the deep via 245 in the silicon substrate 240 as in the third embodiment.

Note that the embodiments described above are merely examples for implementing the present technology, and there is a correspondence relationship between the matter in the embodiments and the claimed subject matter. Likewise, there is a correspondence relationship between the claimed subject matter and the matter in the embodiments of the present technology when those are denoted by the same name. However, the present technology is not limited to the embodiments, and can be implemented by various modifications being made to the embodiments without departing from the scope of the present technology.

Note that effects described herein are not limitative but are merely illustrative, and other effects may be provided.

Note that the present technology may also take the following configurations.

(1) A semiconductor apparatus, including:
a first base substrate that is formed by stacking a first semiconductor substrate and a second semiconductor substrate, the first semiconductor substrate being a semiconductor substrate on which a pixel region that performs photoelectric conversion is formed, the second semiconductor substrate being a semiconductor substrate on which a logic circuit is formed, the logic circuit processing a pixel signal that is output from the pixel region, the first base substrate including a first via that passes through a wiring layer of the logic circuit to a back surface of the first base substrate; and
a second base substrate that includes
   a connection portion that is connected to the first via of the first base substrate on a front surface of the second base substrate, and
   a second via through which the connection portion and an electrode situated in a lowest surface of the second base substrate are electrically connected to each other using a conductive material.
(2) The semiconductor apparatus according to (1), in which
   the second base substrate has a thickness greater than a depth of the first via.
(3) The semiconductor apparatus according to (1) or (2), in which
   the second base substrate includes a plurality of the second vias.
(4) The semiconductor apparatus according to any one of (1) to (3), in which
   the second base substrate includes an insulation layer in which the second via is opened.
(5) The semiconductor apparatus according to (4), in which
   the insulation layer in which the second via is opened is a silicon dioxide film.
(6) The semiconductor apparatus according to any one of (1) to (3), in which
   the second base substrate includes a silicon layer in which the second via is opened.
(7) The semiconductor apparatus according to any one of (1) to (6), in which
   the connection portion of the second base substrate is larger in size than a diameter of the first via.
(8) The semiconductor apparatus according to any one of (1) to (7), in which
   the second base substrate includes a wiring layer on a route that electrically connects the connection portion and the electrode.
(9) The semiconductor apparatus according to any one of (1) to (8), in which
   the second base substrate includes, on the lowest surface, a bump that is electrically connected to the electrode.
(10) A method for manufacturing a semiconductor apparatus, the method including:
   forming a first base substrate by stacking a first semiconductor substrate and a second semiconductor substrate, the first semiconductor substrate being a semiconductor substrate on which a pixel region that performs photoelectric conversion is formed, the second semiconductor substrate being a semiconductor substrate on which a logic circuit is formed, the logic circuit processing a pixel signal that is output from the pixel region;
   forming an insulation film on a back surface of the first base substrate;
   forming a first opening in a conductive material situated inside of the first base substrate;
   forming an insulation film sidewall in the first opening;
   filling a conductive material into a space of the first opening that is situated further inward than the insulation film sidewall;
   smoothing the conductive material;
   forming a second opening in a second base substrate that is different from the first base substrate;
   forming an insulation film on a back surface of the second base substrate;
   filling a conductive material into the second opening;
   smoothing the conductive material;
   bonding the first base substrate and the second base substrate such that the conductive material in the first opening of the first base substrate and the conductive material in the second opening of the second base substrate are connected to each other; and
   removing a substrate of the second base substrate until a portion of a conductive material situated inside of the second base substrate is exposed.
(11) The method for manufacturing a semiconductor apparatus according to (10), in which
   the forming the first opening includes forming the first opening in at least a silicon layer.
(12) The method for manufacturing a semiconductor apparatus according to (10) or (11), further including
   making a material of an upper portion of the first base substrate thinner after the bonding the first base substrate and the second base substrate.
(13) The method for manufacturing a semiconductor apparatus according to (12), in which the material of the upper portion of the first base substrate is silicon.

### REFERENCE SIGNS LIST

10 imaging device
11 pixel
20 vertical drive circuit
30 horizontal drive circuit
40 control circuit
50 column signal processing circuit
59 horizontal signal line
60 output circuit
91 first semiconductor substrate
92 second semiconductor substrate
93 pixel region
94 control circuit
95 logic circuit
100 first base substrate
110 silicon substrate
120, 130 insulation film
140 silicon layer
141 transistor
145 via
150 insulation film
180 on-chip lens
190 to 192 pad electrode
195 conductive material
200 second base substrate
230 insulation film
235, 236 via
240 silicon substrate
245 via
249 insulation film
250 resin
260, 270 insulation film
280 bump
290 to 292 pad electrode
293 wiring layer
295 to 298 conductive material

What is claimed is:

1. A semiconductor apparatus, comprising:
a first base substrate that is formed by stacking a first semiconductor substrate and a second semiconductor substrate, the first semiconductor substrate being a semiconductor substrate on which a pixel region that performs photoelectric conversion is formed, the second semiconductor substrate being a semiconductor substrate on which a logic circuit is formed, the logic circuit processing a pixel signal that is output from the pixel region, the first base substrate including a first via that passes through a wiring layer of the logic circuit to a back surface of the first base substrate; and
a second base substrate that includes
a connection portion that is connected to the first via of the first base substrate on a front surface of the second base substrate, and
a second via through which the connection portion and an electrode situated in a lowest surface of the second base substrate are electrically connected to each other using a conductive material.

2. The semiconductor apparatus according to claim 1, wherein
the second base substrate has a thickness greater than a depth of the first via.

3. The semiconductor apparatus according to claim 1, wherein
the second base substrate includes a plurality of the second vias.

4. The semiconductor apparatus according to claim 1, wherein
the second base substrate includes an insulation layer in which the second via is opened.

5. The semiconductor apparatus according to claim 4, wherein
the insulation layer in which the second via is opened is a silicon dioxide film.

6. The semiconductor apparatus according to claim 1, wherein
the second base substrate includes a silicon layer in which the second via is opened.

7. The semiconductor apparatus according to claim 1, wherein
the connection portion of the second base substrate is larger in size than a diameter of the first via.

8. The semiconductor apparatus according to claim 1, wherein
the second base substrate includes a wiring layer on a route that electrically connects the connection portion and the electrode.

9. The semiconductor apparatus according to claim 1, wherein
the second base substrate includes, on the lowest surface, a bump that is electrically connected to the electrode.

10. A method for manufacturing a semiconductor apparatus, the method comprising:
forming a first base substrate by stacking a first semiconductor substrate and a second semiconductor substrate, the first semiconductor substrate being a semiconductor substrate on which a pixel region that performs photoelectric conversion is formed, the second semiconductor substrate being a semiconductor substrate on which a logic circuit is formed, the logic circuit processing a pixel signal that is output from the pixel region;
forming an insulation film on a back surface of the first base substrate;
forming a first opening in a conductive material situated inside of the first base substrate;
forming an insulation film sidewall in the first opening;
filling a conductive material into a space of the first opening that is situated further inward than the insulation film sidewall;
smoothing the conductive material;
forming a second opening in a second base substrate that is different from the first base substrate;
forming an insulation film on a back surface of the second base substrate;
filling a conductive material into the second opening;
smoothing the conductive material;
bonding the first base substrate and the second base substrate such that the conductive material in the first opening of the first base substrate and the conductive material in the second opening of the second base substrate are connected to each other; and
removing a substrate of the second base substrate until a portion of a conductive material situated inside of the second base substrate is exposed.

11. The method for manufacturing a semiconductor apparatus according to claim 10, wherein
the forming the first opening includes forming the first opening in at least a silicon layer.

12. The method for manufacturing a semiconductor apparatus according to claim 10, further comprising
making a material of an upper portion of the first base substrate thinner after the bonding the first base substrate and the second base substrate.

13. The method for manufacturing a semiconductor apparatus according to claim 12, wherein
the material of the upper portion of the first base substrate is silicon.
